(19) United States
(12) Patent Application Publication
(10) Pub. No.: US 2018/0315484 A1
(43) Pub. Date: Nov. 1, 2018

(54) A METHOD FOR OPERATING A SEMICONDUCTOR MEMORY

(71) Applicant: Institute of Microelectronics, Chinese Academy of Sciences, Chaoyang District, Beijing (CN)

(72) Inventor: Tianchun Ye, Chaoyang District, Beijing (CN)

(21) Appl. No.: 15/769,619

(22) PCT Filed: Nov. 23, 2015
(86) PCT No.: PCT/CN2015/095253

§ 371 Date: Apr. 19, 2018

(30) Foreign Application Priority Data
Oct. 20, 2015 (CN) 201510685366.1

(51) Int. Cl. G11C 16/34; G11C 16/04; G11C 16/08

(52) U.S. Cl. CPC G11C 16/3427; G11C 16/08; G11C 16/0483

(57) ABSTRACT

A method for operating a semiconductor memory includes: randomizing a data of an operation address to obtain a random code; performing a combinational logic operation between the random code and the original data to obtain a randomized data, or performing a combinational logic operation between the randomized data and the random code to obtain a de-randomized data; saving the randomized data, or outputting the de-randomized data. According to the method for operating a semiconductor memory of the present invention, since a combinational logic or a non-iterative sequential logic is used to form a random sequence generation unit, the encoding/decoding process does not need to wait for a specific cycle, thus reducing the operation time and improving the chip performance.

### TECHNICAL FIELD

The present invention relates to a method for operating a non-volatile memory, and more particularly to a method for operating an NAND flash memory.

### TECHNICAL BACKGROUND

Non-volatile storage devices include flash memory, variable impedance storage devices, and the like. Flash memory can be divided into NAND flash memory and NOR flash memory. The structural feature of NOR flash memory is that its memory cells are connected in parallel to bit line. This parallel connection allows random access to the cells of NOR flash memory. In contrast, the structural feature of NAND flash memory is that its memory cells are connected in serial to bit lines. That is, memory cells in a NAND flash memory are connected to a string of memory cells, so only a single connection to the bit line is required. Therefore, NAND flash memory can be very densely integrated.

For a string of cells in a NAND flash memory, the programmed background pattern affects the boost unit which is waiting to be programmed. For the string cells, the concentrated distribution of the state will lead to changes in load towards to drain, which results in reading circuit error. Unevenly distributed programmed state of the NAND flash memory cells will cause some of the cells loss to be excessive until the cells fail. A particular threshold voltage distribution on a string cell will cause SCSL noise when the page read cell is storing data. Randomizing block data can effectively reduce the effect of the above effects and improve chip performance.

FIG. 1A shows a prior art memory structure 100, further including a page buffer circuit 120, a decoder circuit 130, a voltage generator circuit 140, a control logic 150 including a pass/fail check circuit 160, a random data interface component 170, and an input/output buffer circuit 180, wherein the pass/fail check circuit 160 may be configured to be independent of the control logic 150.

FIG. 1B is a block diagram further illustrating the random data interface 170 of FIG. 1A. The random data interface 170 includes an address buffer 171, a random sequence generator 172, a first and a second XOR gates 173a and 173b, a first multiplexer 174, a first and a second odd/even latches 175a and 175b, a flag unit checker 176, a multiplexing controller 177, and a second multiplexer 178. The address buffer 171 is configured to receive an address (for example, a page address) externally supplied together with a normal read command, and then send the received address to the random sequence generator 172 as a seed.

FIG. 1C is a block diagram further illustrating one possible embodiment of the random sequence generator 172 of FIG. 1B. The random sequence generator 172 includes a plurality of flip-flops (for example, 10 flip-flops FF1 to FF10) and an XOR gate G1, that is, a sequential logic circuit is formed by the linear feedback shift register LFSR. The random sequence generator 172 may generate random data according to the seed and clock signals, and then provide the random data to the first and second XOR gates 173a and 173b in FIG. 1B.

FIG. 1D reflects the correspondence between LFSR addresses and encodings during the randomization of FIG. 1C. The data is randomized by the original method. First, the seed data is loaded into the random sequence generator 172, and then in every cycle the unit 172 performs an operation such as shift, XOR and so on to output a state, namely a pseudo-random code. The data is randomly encoded (or decoded) using a pseudo-random code, for example, S0 encodes (or decodes) the data corresponding to the address 0x000. When the first address of read/write operation is 0 address and operates sequentially, the LFSR outputs a corresponding random code in every cycle and completes the encoding/decoding of the data in sequence.

FIG. 1E shows the correspondence between LFSR addresses and encodings during programming. Assuming that the starting address of the programming column is P, then the randomization operation must obtain the corresponding random code S_{P}. For the LFSR structure, the current state is derived from the previous state operation, by analogy, we have to wait for the random sequence to run from S₀ to S_{P} consuming P cycles. There will be 2^{N}−1 random states for a unit with a seed having length N, so p=P mod (2^{N}−1). The waiting clock cycles for read operations are similar to those described above, reducing system efficiency.

FIG. 1F is the correspondence between LFSR addresses and encodings during non-continuous programming. In non-continuous programming of page data, after programming the data corresponding to the column address P, the user jumps to the column address Q to start programming. Because the corresponding random code S_{q} cannot be obtained immediately, the user has to wait for (q−p)mod(2^{N}−1) cycles. Similarly, the non-continuous operation of reading data will have to consume multiple cycles to wait for the random sequence unit to generate random codes, increasing total number of operation cycles, thereby affecting the system performance.

### SUMMARY OF THE INVENTION

From the above, the purpose of the present invention is to overcome the above technical difficulties and to propose a method of operating a semiconductor memory which can effectively reduce the number of operation cycles of the memory to improve the performance of the chip.

To this end, the present invention provides a method for operating a semiconductor memory includes: randomizing a data of an operation address to obtain a random code; performing a combinational logic operation between the random code and the original data to obtain a randomized data, or performing a combinational logic operation between the randomized data and the random code to obtain a de-randomized data; and saving the randomized data, or outputting the de-randomized data.

Wherein the operation address is any one or a combination of a Block Address, a Page Address, a Session Address, and a Column Address.

Wherein the randomizing is implemented by using any one or a combination of four arithmetic operations in a finite field, AND logic, OR logic, SHIFT logic, bit width conversion logic.

Wherein the four arithmetic operations in a finite field includes an affine transformation.

Wherein the randomizing is implemented by using any one or a combination of logic gate, and ROM look-up table method.

Wherein the combined logic operation includes any one or a combination of AND logic, OR logic, NON logic, XOR logic, SHIFT logic, and bit width conversion logic.

Wherein the randomized data is obtained in a hardware manner including various combinational logic implementation methods, non-iterative sequential logic implementation methods, and composite structures thereof.

According to the method for operating a semiconductor memory of the present invention, since a combinational logic is used to form a random sequence generation unit, the encoding/decoding process does not need to wait for a specific cycle, reducing the operation time and improving the chip performance.

### BRIEF DESCRIPTION OF THE DRAWINGS

The technical solutions of the present invention are described in detail below with reference to the accompanying drawings, in which:

FIGS. 1A to 1C are block diagrams of a prior art semiconductor memory structure;

FIGS. 1D to 1F illustrate the correspondence between LFSR addresses and encodings during in the prior art encoding/decoding process;

FIG. 2 is a block diagram of a fast random code generation unit according to the present invention;

FIG. 3 shows the specific structure of the encoding module in the randomization of encoding operation and reading operation;

FIGS. 4 and 5 respectively graphically illustrate the randomization of encoding and reading operations;

FIGS. 6 and 7 respectively show randomization operations according to different embodiments of the present invention.

### DETAILED DESCRIPTION

The features and technical effects of the technical solutions of the present invention will be described in detail below with reference to the accompanying drawings. The semiconductor memory operation method of using combinational logic to form a random sequence generation unit to reduce operation time and improve chip performance is disclosed. It should be noted that similar reference numerals denote similar structures, and the terms “first,” “second,” “upper,” “lower,” and the like as used in this application may be used to modify various device structures or manufacturing processes. These modalities do not imply the spatial, order or hierarchical relationship of the device structure or fabrication process to be modified unless otherwise specified.

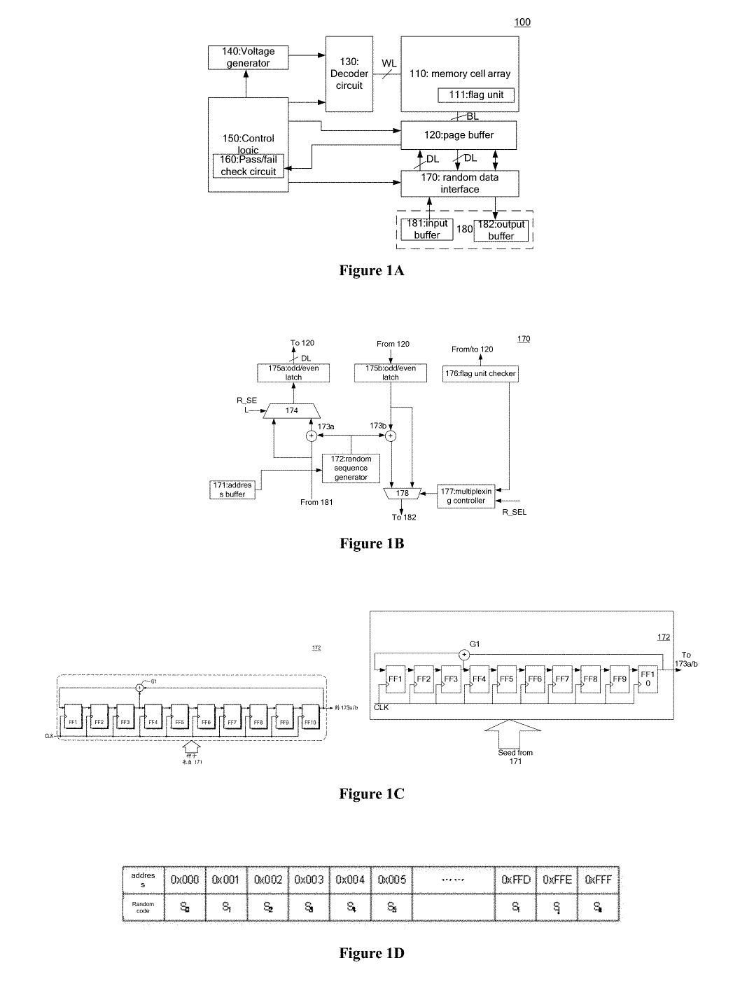

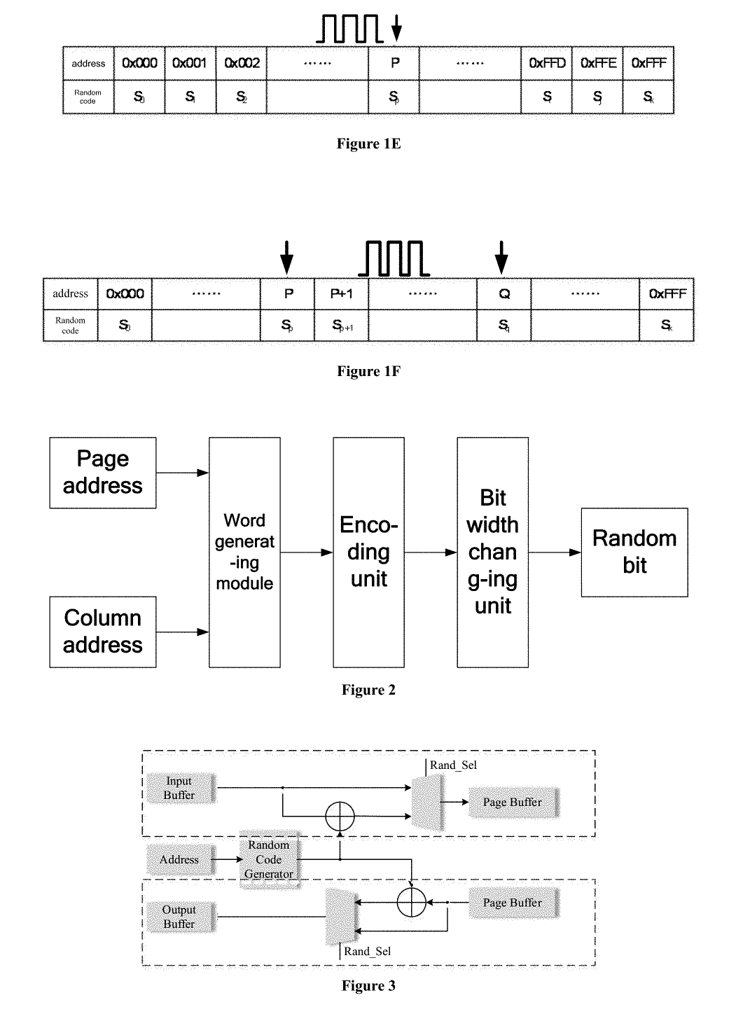

As shown in FIG. 2, a structure of a fast random code generation unit according to the present invention is shown. The memory basic structure of the present invention is similar to that of FIG. 1A and FIG. 1B except that the random sequence is preferably not generated using the sequential logic shown in FIG. 1C. Specifically, for example, the page address and the column address are firstly calculated (the “page address” and the “column address” boxes in FIG. 2 are logically represented as the page address and the column address in the address register, wherein the “page address” may also physically represent the page address part in the address register or can be referred to as page address register, and the “column address” may also physically represent the column address part in the address register or can be referred to as column address register), the word generating module obtains the word to be processed (wherein word is combined by the last M bits of the page address together with the last N bits of the column address. For example, firstly last 3 bits of the page address and secondly last 5 bits of the column address are combined into an 8-bit word), the output of which is loaded into an encoding unit to perform a pseudo-random mapping operation to output a code, this operation is preferably composed by combinational logic. And then the bit width of the generated code is changed by a bit width changing unit, an 1-bit data is fetched and output as a random bit code (the “random bit” box in FIG. 2 can represent a logical output or a physical random bit output buffer or register as well).

FIG. 3 shows a specific structure of an encoding module in a randomization process of an encoding operation and a reading operation. During encoding operation, the input buffer receives the original data and the buffered original data is sent to an input terminal of a selector (multiplexer, such as two selection one). The address of the operation is sent to the random code generator or encoding unit via the address register. The output of the encoding unit and the output of the input buffer are operated via combinational logic (e.g. XOR) and then sent to the other input terminal of the selector. The selector sends the output to the page buffer under the control of the random selection signal. Thus the external information is written into the memory. During decoding namely reading operation, the page buffer data is sent to one input of the selector, the address of the operation is sent to the random code generator or encoding unit via the address buffer. The output of the encoding unit and the output of the input buffer are operated via combinational logic (e.g. XOR) and then sent to the other input terminal of the selector. The selector sends the output to the output buffer under the control of the random selection signal. Thus the information stored in the memory is read out to an external circuit.

Specifically, the operation address may be a block address, a page address, a session address, a column address, or a combined structure thereof (not limited to an 8-bit address), that is to say, the “page address” and “column address” boxes in FIG. 2 may be replaced by other logical addresses in the address registers or partial address registers such as “block address”, “session address” and the like. The mapping coding algorithm of the random code generator or the encoding unit may choose four arithmetic operations in a finite field, various combinational logic such as AND logic, OR logic, SHIFT logic, bit width conversion logic, or the combination structure thereof. The mapping encoding may be achieved via either of logic gates or ROM table lookup method, or combination thereof. The combinatorial logic operations of random bits can be implemented by various combinational logic such as AND logic, OR logic, NON logic, XOR logic, SHIFT logic, bit width conversion logic, or the combination structure thereof.

The random sequence generation unit which is constituted using combinational logic, can instantly provide the required random code during the reading and writing operation at any position. Thus the system can execute the randomized encode process without waiting for a specific period to generate the corresponding random code by the random sequence unit. Because Word's data source contains the page address and the column address, a randomized distribution at two dimensions of string and page in memory can be achieved. Therefore, this method is an effective way to improve the chip performance.

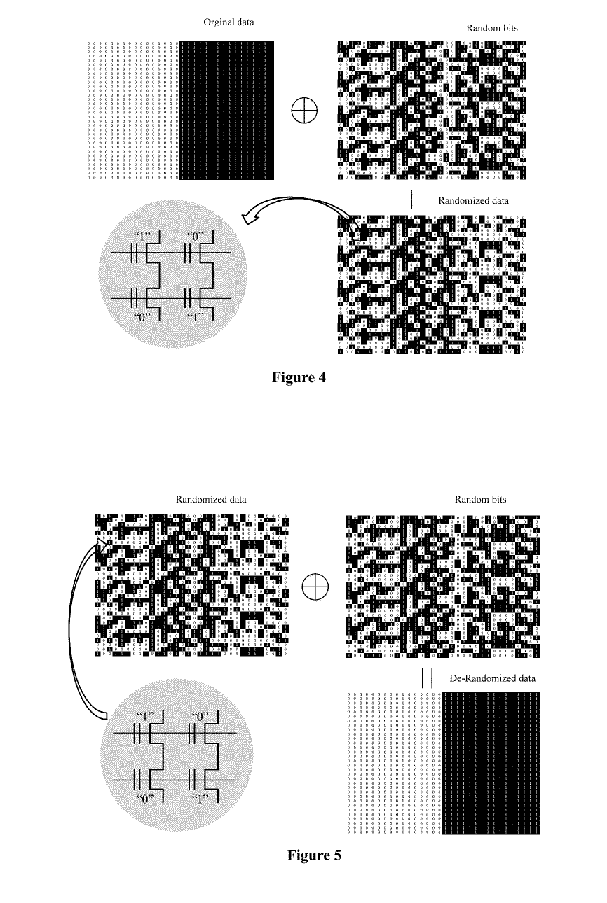

FIGS. 4 and 5 graphically show the randomization of encoding and reading operations, respectively. FIG. 4 show s an encoding operation, wherein the balanced distributed original data (for example, the left side all white “0” while the right side all black “1”) and the unbalanced distributed random bits (generated by the random data Generator or the encoding unit in FIGS. 2 and 3) are performed by combinational logic operation such as XOR to obtain randomized data. FIG. 5 is a decoding/reading operation, wherein the randomized data are read from the memory through the page buffer and then combinational logic operated with a random bit such as XOR or the like, and finally balanced distributed (for example, the left side all white “0” while the right side all “1”) de-randomized data are output.

Referring to FIG. 1E, taking a programming operation as an example, it is assumed that a programming column start address is P, since the random code generated by the present method is irrelevant to the previous state, the currently required random state Sₚ will be obtained via pseudo-random mapping operation after the current page address and the column address are input. Similarly, the reading operations do not need to wait for executing a particular cycle by the random sequence unit, thus reducing the number of operation cycles and improving system performance.

Referring to FIG. 1F, when the page data is programmed discontinuously, after programming the data corresponding to the column address P, the user jumps to the column address Q to start programming via a command. In order to randomize data by this present method, it only needs to perform a pseudo-random mapping operation on the page address and column address corresponding to Q via a combinational logic structure, a random code S_{q} will be generated and the encoding/decoding be completed. Similarly, the operation of reading data from non-consecutive rows does not need to consume multiple cycles to wait for the random sequence unit to generate a random code, thereby reducing the total number of operation cycles and improving system performance.

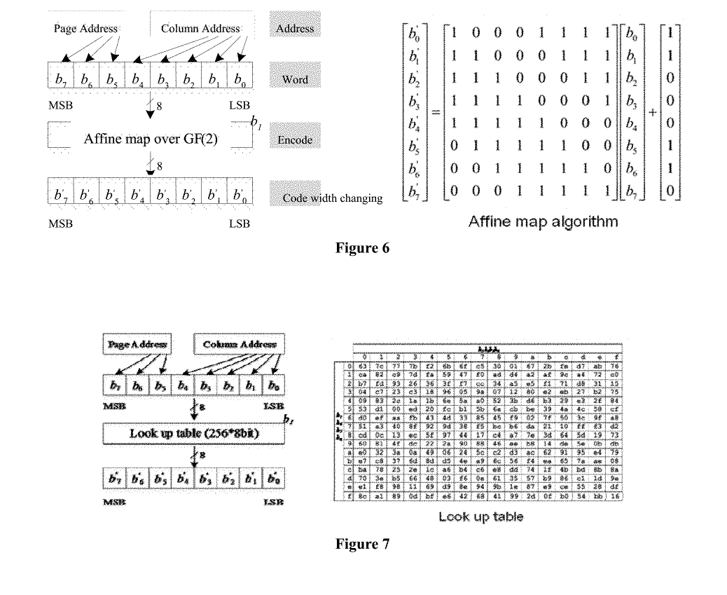

FIG. 6 shows a randomizing operation according to the first embodiment of the present invention, that is, a specific generating process of a random code. The page address and the row address are obtained from the address buffer, and the last 3 bits of the page address and the last 5 bits of the column address are spliced to form a Word with a bit width of 8 bits, wherein MSB is the highest bit and LSB is the lowest bit. An 8-bit wide random code is then generated by the encoding unit, i.e. random code generator. Among them, the encoding unit uses the affine transformation operation of GF (2) in the Galois field involving the multiplication and addition of finite fields. The specific transformation of each bit is shown as operation matrix in the right figure. Random bit can directly take the last Code, i.e. b′₀. The algorithm is implemented using combinational logic.

FIG. 7 shows a randomizing operation according to the second embodiment of the present invention. As shown in left part of this figure, the Word bit width is set as 8, which is spliced by the last 3 bits of the page address and the last 5 bits of the column address, an 8-bit wide random code is output from the Encode pseudo-random mapping unit. Encode unit is implemented by adopting Look up table method, wherein firstly storing a look-up table with a depth of 256 and a width of 8 bits into the system, and then taking the Word as the addressing value to fetch the corresponding random code during operation. Random bits can directly take the last bit of the Code, i.e. b′₀. This method trades area for speed, consuming certain resources to improve system speed.

Although the above embodiments of the present invention are directed to a NAND flash memory structure, they are also applicable to other memory structure systems such as a NOR flash memory, a SLC, a multi-bit memory cell (MLC, TLC, QLC) and the like.

In addition, although the above technical solutions emphasize that the pseudo-random mapping coding is implemented in a hardware manner of combinational logic, obtaining the randomized data by hardware may also actually include various combinatorial logic implementation methods, non-iterative sequential logic implementation methods and the composite structures thereof.

According to the semiconductor memory operating methods of the present invention, since a combinational logic is used to form a random sequence generation unit, the encoding process does not need to wait for a specific cycle, reducing the operation time and improving the chip performance.

Although the present invention has been described with reference to one or more exemplary embodiments, those skilled in the art can appreciate various suitable modifications and equivalent arrangements to the device structure or method without departing from the scope of the present invention. In addition, many modifications may be made to adapt a particular situation or material to the teachings of the disclosure without departing from the scope of the invention. Therefore, it is intended that the invention not be limited to the particular embodiments disclosed as the best mode contemplated for carrying out this invention, the disclosed device structures and methods of manufacture will include all embodiments falling within the scope of the invention.

1. A method for operating a semiconductor memory includes:
randomizing a data of an operation address to obtain a random code;
performing a combinational logic operation between the random code and an original data to obtain a randomized data, or performing a combinational logic operation between the randomized data and the random code to obtain a de-randomized data;
saving the randomized data, or outputting the de-randomized data.

2. The method of claim 1, wherein the operation address is any one or a combination of a Block Address, a Page Address, a Session Address, and a Column Address.

3. The method of claim 1, wherein the randomizing is implemented by using any one or a combination of four arithmetic operations in a finite field, AND logic, OR logic, SHIFT logic, bit width conversion logic, and non-iterative sequential logic.

4. The method of claim 3, wherein the four arithmetic operations in a finite field include an affine transformation.

5. The method of claim 3, wherein the randomizing is implemented by using any one or a combination of logic gate, and ROM look-up table method.

6. The method of claim 1, wherein the combinational logic operation includes any one or a combination of AND logic, OR logic, NON logic, XOR logic, SHIFT logic, and bit width conversion logic.

7. The method of claim 1, wherein the randomized data is obtained in a hardware manner including various combined logic implementation methods, non-iterative sequential logic implementation methods, and composite structures thereof.
